(19) United States
(12) Patent Application Publication
(10) Pub. No.: US 2025/0268073 A1
(43) Pub. Date: Aug. 21, 2025

(54) Display Apparatus

(71) Applicant: LG Display Co., Ltd., Seoul (KR)

(72) Inventor: Jongmoo Ha, Gimpo-si (KR)

(21) Appl. No.: 19/051,587

(22) Filed: Feb. 12, 2025

(30) Foreign Application Priority Data
Feb. 16, 2024 (KR) 10-2024-0022561

(51) Int. Cl. H10K 59/80

(52) U.S. Cl. CPC H10K 59/873; H10K 59/80518

(57) ABSTRACT

A display apparatus includes a substrate including a display area, and a non-display area surrounding at least a portion of the display area, wherein a light-emitting element is disposed on the display area; a dam disposed on the non-display area; a stopper structure disposed on the non-display area, wherein the stopper structure is positioned between the dam and the display area; and a first electrode of the light-emitting element, wherein the first electrode extends from the display area to the non-display area, wherein the first electrode includes a plurality of openings, and wherein the plurality of openings disposed on the non-display area of the substrate.

### CROSS-REFERENCE TO RELATED APPLICATION

This application claims priority from Republic of Korea Patent Application No. 10-2024-0022561 filed on Feb. 16, 2024 in the Korean Intellectual Property Office, which is hereby incorporated by reference in its entirety.

### BACKGROUND

### Field

The present disclosure relates to a display apparatus.

### Description of Related Art

Display apparatuses are applied to various electronic devices such as TVs, smartphones, laptops, and tablets. To this end, research is being conducted to develop smaller, lighter, and lower power consuming display devices.

Examples of the display apparatus include a liquid crystal display apparatus (LCD), a field emission display apparatus (FED), and an organic light emitting display apparatus (OLED).

### SUMMARY

The organic light-emitting display apparatus includes an organic material that is vulnerable to moisture or oxygen. When the organic material is exposed to moisture or oxygen, problems such as dark spots, shrinkage of an area of the sub-pixel, or oxidation of an electrode may occur.

Accordingly, an encapsulation portion is included to prevent the organic light-emitting display apparatus from being exposed to the moisture or oxygen.

A technical purpose according to an embodiment of the present disclosure is to provide a display apparatus in which a first electrode is disposed on a dam such that a shape of an inclined surface of the dam is maintained.

Another technical purpose according to an embodiment of the present disclosure is to provide a display apparatus in which the shape of the inclined surface of the dam is maintained to prevent formation of a seam that may act as a moisture penetration path in a process of forming insulating films.

Furthermore, still another technical purpose according to an embodiment of the present disclosure is to provide a display apparatus in which the formation of the seam is suppressed to prevent moisture or oxygen from penetrating into a display area through an encapsulation portion, thereby preventing occurrence of a pixel defect.

Purposes according to the present disclosure are not limited to the above-mentioned purpose. Other purposes and advantages according to the present disclosure that are not mentioned may be understood based on following descriptions and may be more clearly understood based on embodiments according to the present disclosure. Further, it will be easily understood that the purposes and advantages according to the present disclosure may be realized using means shown in the claims or combinations thereof.

A display apparatus includes a substrate including a display area, and a non-display area surrounding at least a portion of the display area, wherein a light-emitting element is disposed in the display area; a dam disposed in the non-display area; a stopper structure disposed in the non-display area, wherein the stopper structure is positioned between the dam and the display area; and a first electrode of the light-emitting element, wherein the first electrode extends from the display area to the non-display area, wherein the first electrode includes a plurality of openings, and wherein the plurality of openings are disposed in the non-display area of the substrate.

According to an embodiment of the present disclosure, the stopper structure is disposed in the non-display area and at a position located between the dam and the display area, and the encapsulation portion is disposed on the stopper structure, thereby preventing or reducing external moisture or oxygen from penetrating into the display area.

According to an embodiment of the present disclosure, the shape of the inclined surface of the dam may be maintained by adjusting a size of the area in which the first electrode is disposed on the inclined surface of the dam. Maintaining the shape of the inclined surface of the dam may allow formation of the seam that may act as the moisture penetration path to be prevented in the process of forming insulating films.

Accordingly, the dark spot in which a pixel does not emit light, reduction of luminance, and a defect in which the electrode is oxidized, due to the moisture penetration may be suppressed. As a result, a display apparatus capable of operating at low power and reducing power consumption may be provided.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

FIG. 1 is a plan view of a display apparatus according to one embodiment of the present disclosure.

FIG. 2 is a side elevation view showing the display apparatus of FIG. 1 according to one embodiment of the present disclosure.

FIG. 3 is a cross-sectional view showing one sub-pixel of the display apparatus of FIG. 1 according to one embodiment of the present disclosure.

FIG. 4 and FIG. 5 are enlarged plan views showing an area 4 of FIG. 1 according to one embodiment of the present disclosure.

FIG. 6 is a cross-sectional view taken along a line 6-6 of FIG. 5 according to one embodiment of the present disclosure.

FIGS. 7A and 7B are diagrams showing a shape of an inclined surface of a dam.

FIGS. 8 to 10 are diagrams showing another embodiment of the present disclosure.

FIGS. 11 to 13 are diagrams showing still another embodiment of the present disclosure.

FIGS. 14 and 15 are diagrams showing still yet another embodiment of the present disclosure.

FIGS. 16 and 17 are diagrams showing still yet another embodiment of the present disclosure.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element or layer may be disposed directly on the second element or layer, or it may be disposed indirectly on the second element or layer with a third element or layer being disposed between the first and second elements or layers. It will be understood that when a first element or layer is referred to as being “connected to”, or “coupled to” a second element or layer, the first element or layer may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

In descriptions of temporal relationships, for example, temporal precedent relationships between two events using terms such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or period from another element, component, region, layer or period. Thus, a first element, component, region, layer or period as described under could be termed a second element, component, region, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects”, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description part. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

Hereinafter, a display apparatus according to each of embodiments of the present disclosure is described with reference to the attached drawings.

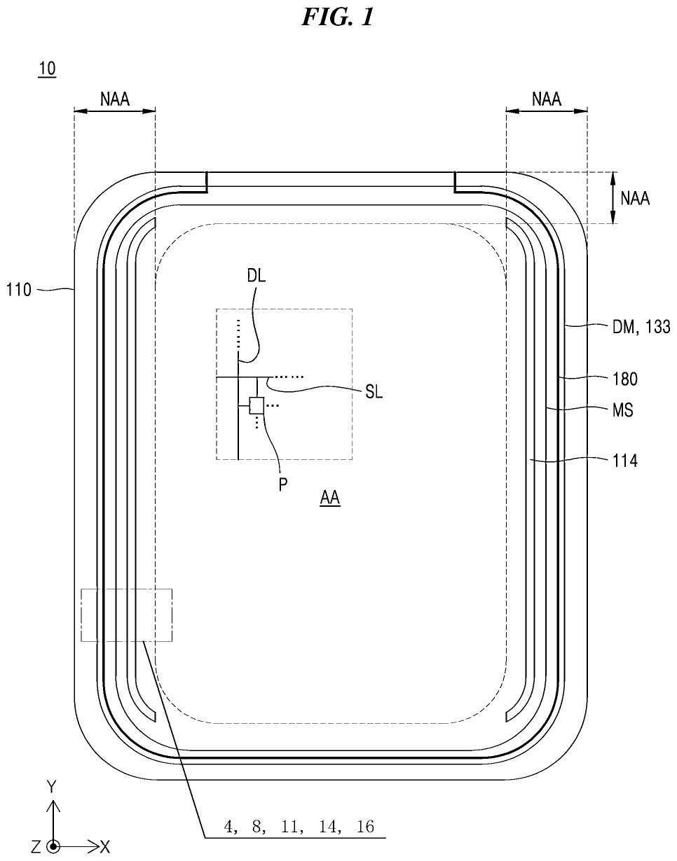

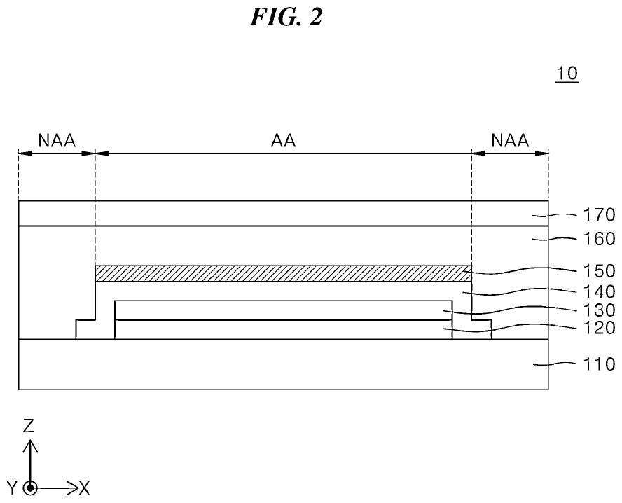

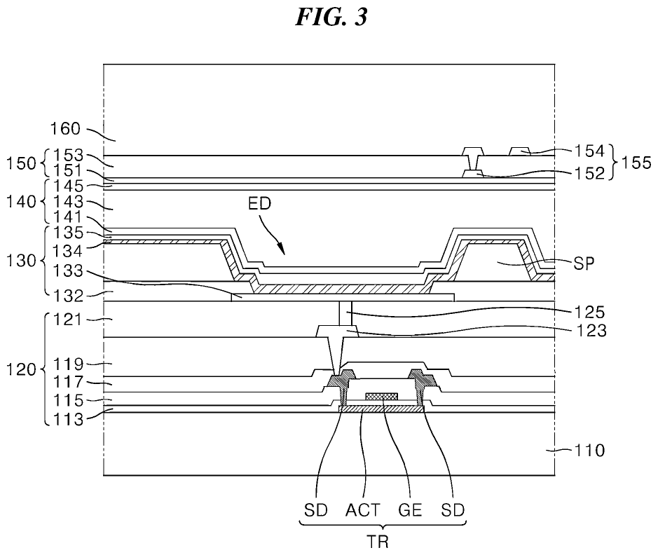

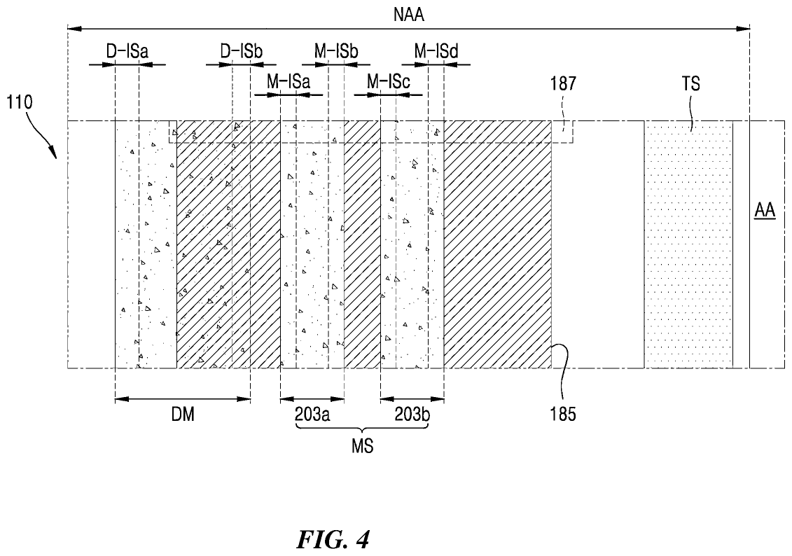

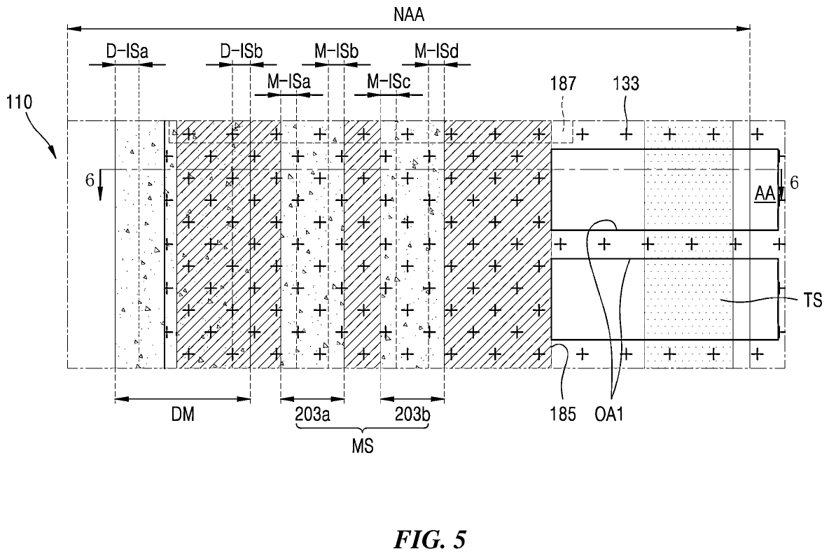

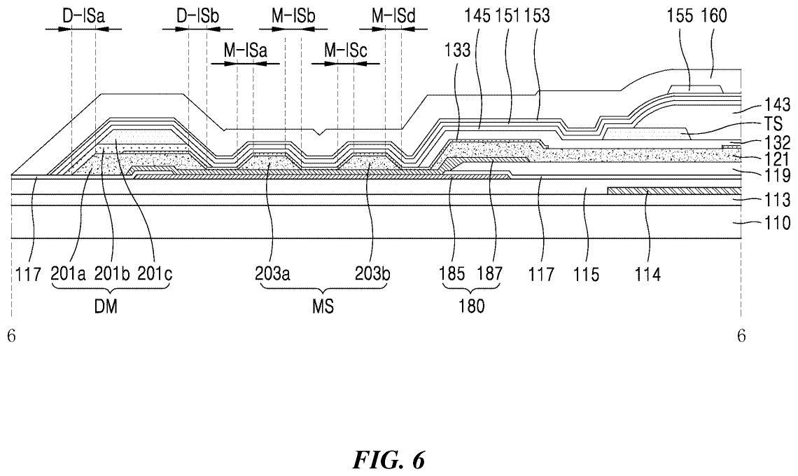

FIG. 1 is a plan view of a display apparatus according to one embodiment of the present disclosure. FIG. 2 is a side elevation view showing of the display apparatus of FIG. 1 according to one embodiment of the present disclosure. FIG. 3 is a cross-sectional view showing one sub-pixel of the display apparatus of FIG. 1 according to one embodiment of the present disclosure. FIG. 4 and FIG. 5 are enlarged plan views showing an area 4 of FIG. 1 according to one embodiment of the present disclosure. FIG. 6 is a cross-sectional view along a line 6-6 of FIG. 5 according to one embodiment of the present disclosure. For convenience of illustration, FIG. 4 shows a dam DM, a plurality of stopper structures MS and TS, a first power line 185, and a second power line 187. Furthermore, FIG. 5 is a diagram further including a first electrode 133 in FIG. 4.

Referring to FIGS. 1 to 3, a display apparatus 10 according to an embodiment of the present disclosure may include a first substrate 110 having a display area AA and a non-display area NAA located outside the display area AA, and a second substrate 170 attached to the first substrate 110. The reference signs 4, 8, 11, 14 and 17 shown in FIG. 1 shows areas 4, 8, 11, and 17, respectively.

The first substrate 110 may include a transparent plastic or glass material. The second substrate 170 may include a transparent plastic film, a glass substrate, or an encapsulating film.

In a plan view, the first substrate 110 or the second substrate 170 may have a rectangular shape having a short side in a first direction and a long side in a second direction. Alternatively, the first substrate 110 or the second substrate 170 may have a square shape with rounded four corners. However, embodiments of the present disclosure are not limited thereto. The first direction may be, for example, an X-axis direction or a row direction in a plan view of the first substrate 110, and the second direction may be, for example, a Y-axis direction or a column direction in a plan view of the first substrate 110. However, embodiments of the present disclosure are not limited thereto. The second substrate 170 may be referred to as a cover window, a window cover, or a cover glass covering the first substrate 110.

A plurality of pixels P may be disposed in the display area AA. An image or video may be displayed in the display area AA through the plurality of pixels P. The non-display area NAA may be an area surrounding at least a portion of the display area AA. The non-display area NAA may be a bezel area. However, embodiments of the present disclosure are not limited thereto.

In the non-display area NAA, several drivers for driving the plurality of pixels disposed in the display area AA may be disposed. For example, the drivers may include, but are not limited to, a gate driver, a data driver, a touch driver, and a timing controller.

Referring to FIG. 2, the display apparatus 10 may include a structure in which the first substrate 110 and the second substrate 170 are bonded to each other. A transistor array 120, a light-emitting array 130, an encapsulation stack 140, and a touch stack 150 may be disposed between the first substrate 110 and the second substrate 170. For example, the first substrate 110 and the second substrate 170 may be bonded to each other via a sealing layer 160.

The transistor array 120 may be disposed on the first substrate 110. The transistor array 120 may include a plurality of transistors, a plurality of scan lines, and a plurality of data lines. A description of the transistor array 120 will be set forth in detail below with reference to FIG. 3.

The light-emitting array 130 is disposed on the transistor array 120. Referring to FIG. 3, a light-emitting element ED having a structure in which the first electrode 133, a light-emitting stack 134, and a second electrode 135 are stacked may be included in the light-emitting array 130. The light-emitting stack 134 may be an organic light-emitting layer including an organic material. A driving current may be applied to the first electrode 133 and the second electrode 135 respectively located under and on top of the light-emitting stack 134, so that light may be emitted from the light-emitting stack 134.

The first electrode 133 may also be referred to as an anode electrode or a pixel electrode, and the second electrode 135 may also be referred to as a cathode electrode or a counter electrode. The first electrode 133 may include a transparent metal oxide such as indium tin oxide (ITO) or indium zinc oxide (IZO). Furthermore, the first electrode 133 may include a single-layer or multi-layer structure including a reflective metal film made of silver (Ag), aluminum (Al), gold (Au), nickel (Ni), chromium (Cr), and compounds thereof. The light-emitting array 130 will be described in detail below with reference to FIG. 3.

The encapsulation stack 140 may be disposed on the light-emitting array 130. The light-emitting stack 134 includes an organic material and is therefore vulnerable to oxygen and moisture.

Accordingly, the encapsulation stack 140 may seal the light-emitting stack 134 including the organic material to prevent or at least reduce oxygen or moisture from penetrating into the light-emitting stack 134. The encapsulation stack 140 may include an inorganic insulating layer or an organic insulating layer having a multilayer structure. The encapsulation stack 140 will be described in detail below with reference to FIG. 3.

The touch stack 150 may be disposed on the encapsulation stack 140. The touch stack 150 may include a plurality of touch electrodes for detecting a user's touch, bridge electrodes for electrically connecting adjacent touch electrodes to each other, and a protective layer for protecting the touch electrodes. The touch stack 150 will be described in detail below with reference to FIG. 3. The sealing layer 160 may be disposed to cover the touch stack 150 and be located between the first substrate 110 and the second substrate 170. The sealing layer 160 may further include an adhesive member that improves the adhesion between the first substrate 110 and the second substrate 170.

Referring to FIG. 1 and FIG. 2, a plurality of data lines DL and a plurality of scan lines SL may be disposed in the display area AA of the first substrate 110. The plurality of data lines DL and the plurality of scan lines SL may be located on the transistor array 120. Each of the plurality of data lines DL may extend to intersect with each of the plurality of scan lines SL. A pixel P is disposed in an area defined by each of the data lines DL and each of the scan lines SL that intersect each other. A plurality of pixels P may be disposed in the display area AA. A single pixel P may include a plurality of sub-pixels. For example, each of the sub-pixels may be electrically connected to the scan line and the data line.

One scan line SL extends along the first direction of the first substrate 110. The plurality of scan lines SL may be arranged to be spaced apart from each other in the second direction intersecting the first direction. One data line DL extends along the second direction. The plurality of data lines DL may be arranged to be spaced apart from each other in the first direction intersecting the second direction. The first direction may be the X-axis direction or the row direction in the plan view of the first substrate 110, and the second direction may be the Y-axis direction or the column direction in the plan view of the first substrate 110. However, embodiments of the present disclosure are not limited thereto.

The plurality of sub-pixels constituting one pixel P may be arranged in a matrix manner (M * N, M and N are natural numbers) in the display area AA of the first substrate 110. However, embodiments of the present disclosure are not limited thereto. Each sub-pixel may have a light-emitting element positioned therein to emit red, green, or blue light.

A gate driver 114 may be disposed in the non-display area NAA surrounding the display area AA. The gate driver 114 may be located in the non-display area NAA of at least one side area of the first substrate 110. The gate driver 114 may include a plurality of gate driving circuits. The gate driver 114 may be disposed in a gate-in-panel (GIP) manner. For example, the gate driver 114 may provide a scan signal to selected sub-pixels through the scan line SL. The gate driver 114 may be formed directly on the first substrate 110.

The gate driver 114 may be disposed between the dam DM and the display area AA. The first voltage line 185 and the plurality of stopper structures TS and MS may be disposed between the dam DM and the gate driver 114. The plurality of stopper structures TS and MS may include a first stopper structure TS and a second stopper structure MS. The first stopper structure TS (refer to FIG. 6) may be disposed to overlap the gate driver 114 in the vertical direction. However, embodiments of the present disclosure are not limited thereto. The second stopper structure MS may be disposed between the gate driver 114 and the dam DM.

A voltage line 180 may be disposed in the non-display area NAA. For example, the voltage line 180 may be a high-potential voltage line and/or a low-potential voltage line. However, embodiments of the present disclosure are not limited thereto. The voltage line 180 may include the first voltage line 185 (refer to FIG. 6) and the second voltage line 187 (refer to FIG. 6). The first voltage line 185 and the second voltage line 187 may be disposed in different layers.

The voltage line 180 may be electrically connected to a pad disposed at one side area of the non-display area NAA. The pad may include a metal pattern to which a flexible printed circuit board (FPCB) and a printed circuit board (PCB) are attached.

The printed circuit board may include an integrated circuit chip and provide power and various signals for driving the light-emitting element to the display area AA. For example, the various signals may include a high-potential voltage, a low-potential voltage, a scan signal, a data signal, or a touch driving signal.

The first electrode 133 may extend from the display area AA to the non-display area NAA. For example, the first electrode 133 may be disposed to overlap at least a portion of the dam DM. As the first electrode 133 is disposed to extend to the non-display area NAA, an area size thereof in contact with the voltage line 180 may increase. As the contact area of the first electrode 133 with the voltage line 180 increases, electrical resistance may decrease. For example, the voltage line 180 may be a Vss electrode.

The dam DM may be disposed in the non-display area NAA. The dam DM may have a closed curve shape surrounding at least a portion of the display area AA. The dam DM may prevent the organic insulating material from the encapsulation stack 140 that seals the transistor array 120 and the light-emitting array 130 from overflowing.

Referring to FIG. 1 and FIGS. 4 to 6, each of the plurality of stopper structures TS and MS may include a closed curve shape surrounding the display area AA. The second stopper structure MS may have a closed curve shape surrounding at least a portion of an outer perimeter of the first stopper structure TS in the plan view. Among the plurality of stopper structures TS and MS, the first stopper structure TS (refer to FIG. 6) may be closer to the display area AA than the second stopper structure MS may be. The second stopper structure MS may be disposed in an area between the dam DM and the first stopper structure TS. The second stopper structure MS may be disposed to surround at least a portion of the first stopper structure TS while the first stopper structure TS is disposed between the second stopper structure MS and the display area AA. Accordingly, the second stopper structure MS may have a relatively larger diameter size than that of the first stopper structure TS. In one example, the second stopper structure MS may include a plurality of patterns.

In an embodiment of the present disclosure, the first stopper structure TS, the second stopper structure MS, and the dam DM may be disposed on a portion of the non-display area NAA surrounding at least a portion of an outer perimeter of the display area AA and may be sequentially arranged in an outward direction from a position closer to the display area AA, such that the organic insulating material may be prevented from overflowing.

Referring to FIGS. 3 to 6, a transistor TR may be disposed on the first substrate 110. The transistor TR may include a semiconductor layer ACT, a gate insulating layer 113, a gate electrode GE, and a source/drain electrodes SD.

A buffer layer (not shown) may be further disposed between the first substrate 110 and the transistor TR. The buffer layer may protect the transistor TR by reducing or preventing the penetration of moisture, oxygen, or impurities into the transistor TR through the first substrate 110. The buffer layer may include a single layer or a stack of multiple layers made of an inorganic insulating material.

The semiconductor layer ACT may include an oxide-based semiconductor material or a silicon-based semiconductor material. For example, the semiconductor layer ACT may include a transparent oxide semiconductor material such as indium-gallium-zinc-oxide (IGZO) or indium-zinc-oxide (IZO). Alternatively, the semiconductor layer ACT may include low-temperature polysilicon. However, embodiments of the present disclosure are not limited thereto. The semiconductor layer ACT may include a channel area and a source/drain area.

The gate insulating layer 113 may be disposed between the semiconductor layer ACT and the gate electrode GE. The gate insulating layer 113 may be composed of a single layer or a plurality of layers made of silicon oxide (SiOx) or silicon nitride (SiNx). However, embodiments of the present disclosure are not limited thereto.

The gate electrode GE may be disposed on the gate insulating layer 113. The gate electrode GE may be formed as a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited to these materials.

An area of the semiconductor layer ACT overlapping the gate electrode GE in the vertical direction may be a channel area. The source/drain areas may be located on both opposing sides of the channel area, respectively.

A first interlayer insulating layer 115 may be disposed on the gate electrode GE. The first interlayer insulating layer 115 may cover the gate electrode GE. The source/drain electrodes SD may be disposed on the first interlayer insulating layer 115. The source/drain electrodes SD may extend through the first interlayer insulating layer 115 and the gate insulating layer 113 so as to be electrically connected to the source/drain areas of the semiconductor layer ACT, respectively.

In the non-display area NAA, the first voltage line 185 may be disposed at a different location from a location of the source/drain electrodes SD. For example, the first voltage line 185 may be a Vss electrode. Referring to FIG. 4 and FIG. 6, at least one partial area of the first voltage line 185 may overlap with the dam DM while at least another partial area of the first voltage line 185 may overlap with the second stopper structure MS in the vertical direction. The first voltage line 185 may be disposed on the first interlayer insulating layer 115 and in the non-display area NAA. For example, the first voltage line 185 and the source/drain electrodes SD may be formed in the same process and may include the same material.

A second interlayer insulating layer 117 may be disposed on the first interlayer insulating layer 115. The first interlayer insulating layer 115 or the second interlayer insulating layer 117 may include an inorganic insulating film including silicon oxide (SiOx) or silicon nitride (SiNx). However, embodiments of the present disclosure are not limited thereto.

A planarization layers 119 and 121 may be disposed on the second interlayer insulating layer 117. The planarization layers 119 and 121 may include the first planarization layer 119 and the second planarization layer 121.

The first planarization layer 119 may planarize a step generated by an underlying circuit element including the transistor TR. The first planarization layer 119 may include an organic insulating material such as an acryl resin, an epoxy resin, a phenolic resin, a polyamide resin, or a polyimide resin. However, embodiments of the present disclosure are not limited thereto, and the first planarization layer 119 may include an organic insulating material capable of planarizing the step.

The first planarization layer 119 may receive therein a contact hole exposing a portion of an upper surface of one of the source/drain electrodes SD of the transistor TR. A first contact electrode 123 may be disposed on the first planarization layer 119. The first contact electrode 123 may extend along a portion of an upper surface of the first planarization layer 119 while filling the contact hole. Thus, the first contact electrode 123 may contact one of the source/drain electrodes SD.

For example, the second voltage line 187 may be disposed in the non-display area NAA. Referring to FIG. 4 and FIG. 6, the second voltage line 187 may be disposed such that at least one partial area thereof overlaps the dam DM and at least another partial area thereof overlaps the second stopper structure MS in the vertical direction. A portion of the second voltage line 187 overlapping the second stopper structure MS may be in contact with the first voltage line 185. The second voltage line 187 may be disposed on the first planarization layer 119 and in the non-display area NAA.

The second planarization layer 121 may be disposed on the first contact electrode 123. The second planarization layer 121 may receive therein a contact hole exposing a portion of an upper surface of the first contact electrode 123. The contact hole extending through the second planarization layer 121 may be filled with a second contact electrode 125. A lower surface of the second contact electrode 125 may be in contact with and electrically connected to the first contact electrode 123.

The light-emitting array 130 may be disposed on the second planarization layer 127. The light-emitting array 130 may include a bank 132, a plurality of light-emitting elements ED, and a spacer SP. Each of the plurality of light-emitting elements ED may include the first electrode 133, the light-emitting stack 134, and the second electrode 135. In this regard, the first electrode 133 may also be referred to as an anode electrode or a pixel electrode, and the second electrode 135 may also be referred to as a cathode electrode or a counter electrode.

The first electrode 133 may be positioned on the second planarization layer 121. A lower surface of the first electrode 133 may be in contact with an upper surface of the second contact electrode 125. Accordingly, the first electrode 133 may be electrically connected to one of the source/drain electrodes SD of the transistor TR via the second contact electrode 125 and the first contact electrode 123.

The first electrode 133 may include a transparent metal oxide such as indium tin oxide (ITO) or indium zinc oxide (IZO). Alternatively, the first electrode 133 may include a single-layer or multi-layer structure including a reflective metal film made of silver (Ag), aluminum (Al), gold (Au), nickel (Ni), chromium (Cr), and/or compounds thereof.

Referring to FIG. 3, FIG. 5, and FIG. 6, the first electrode 133 may be disposed to extend from the display area AA to the non-display area NAA. The first electrode 133 may extend to the non-display area NAA so as to overlap at least a partial area of the dam DM.

The first electrode 133 may have an opening OA1 defined therein. The opening OA1 defined in the first electrode 133 may prevent or at least reduce the occurrence of parasitic capacitance. For example, when a circuit pattern is disposed between the first electrode 133 and the second electrode 135 or is disposed so as to overlap the first electrode 133 in the vertical direction in an area other than an area where the light-emitting element ED has been formed, the parasitic capacitance may occur. For this reason, the opening OA1 may be defined in the first electrode 133 in a portion of the non-display area NAA adjacent to the display area AA and in an area where the circuit pattern is disposed so as to vertically overlap the first electrode 133, thus the occurrence of the parasitic capacitance may be prevented or minimized.

Referring to FIG. 5, the first electrode 133 according to one embodiment of the present disclosure may overlap the dam DM and the second stopper structure MS in the vertical direction. A plurality of openings OA1 defined in the first electrode 133 may overlap a partial area of the first stopper structure TS.

The bank 132 may be disposed on the second planarization layer 121. The bank 132 serves to distinguish the sub-pixels from each other. For this purpose, the bank 132 may be formed to cover an edge of the first electrode 133. Furthermore, the bank 132 may prevent light beams of different colors output from adjacent sub-pixels from being mixed with each other. The bank 132 may include an organic insulating film made of, for example, polyimide or epoxy. However, embodiments of the present disclosure are not limited thereto. The bank 132 may include a transparent organic insulating material.

The spacer SP may be disposed on the bank 132. The spacer SP may include the same material as a material of the bank 132. The spacer SP may protect the light-emitting stack 134 from being directly subjected to an external impact.

Referring again to FIG. 3, FIG. 4, and FIG. 6, the first stopper structure TS may be formed in a process of forming the spacer SP. The first stopper structure TS may be disposed closest to the display area AA so as to prevent or reduce overflow of the organic insulating material. The first stopper structure TS may include the same material as a material of the bank 132 or the spacer SP. However, embodiments of the present disclosure are not limited thereto.

The dam DM may include a structure in which a first layer 201a formed in a process of forming the second planarization layer 121, a second layer 201b formed in a process of forming the bank 132, and a third layer 201c formed in a process of forming the spacer SP are sequentially stacked vertically and upwardly. However, embodiments of the present disclosure are not limited thereto. The first layer 201a of the dam DM may include the same insulating material as that of the second planarization layer 121, the second layer 201b may include the same insulating material as that of the bank 132, and the third layer 201c may include the same insulating material as that of the spacer SP. The first stopper structure TS may include the same material as a material of the third layer 201c of the dam DM.

The first layer 201a of the dam DM may have a smaller width or size than that of the second layer 201b. The second layer 201b may cover the first layer 201a. The third layer 201c may cover an upper surface of the second layer 201b. However, embodiments of the present disclosure are not limited thereto.

Referring to FIG. 6, the second stopper structure MS may include a plurality of patterns arranged so as to be spaced apart from each other. The first electrode 133 may be disposed in a space between adjacent ones of the plurality of patterns. At least one of the plurality of openings defined in the first electrode 133 may at least partially overlap an inclined surface of the second stopper structure MS vertically. For example, the second stopper structure MS may include a first stopper pattern 203a and a second stopper pattern 203b. The first stopper pattern 203a and the second stopper pattern 203b may be spaced from each other. In one embodiment of the present disclosure, two stopper patterns 203a and 203b are illustrated. However, the present disclosure is not limited thereto.

The second stopper structure MS may include the same material as a material of the bank 132 or the spacer SP. However, embodiments of the present disclosure are not limited thereto. The second stopper structure MS and the first layer 201a of the dam DM may be formed of a same material in a same layer together in the process of forming the second planarization layer 121. The second stopper structure MS may have the same shape as that of the first layer 201a of the dam DM. Accordingly, the second stopper structure MS may have a vertical dimension smaller than a vertical dimension of the dam DM.

For example, the first layer 201a of the dam DM may include an upper surface and both opposing inclined surfaces D-ISa and D-ISb extending downwardly from both opposing sides of the upper surface, respectively. The inclined surfaces D-ISa and D-ISb may include a first inclined surface D-ISa extending from one side of the upper surface and a second inclined surface D-ISb extending from the other side thereof.

The first stopper pattern 203a of the second stopper structure MS may include an upper surface and both opposing inclined surfaces M-ISa and M-ISb extending downwardly from both opposing sides of the upper surface, respectively. The inclined surfaces M-ISa and M-ISb of the first stopper pattern 203a may include a first inclined surface M-ISa extending from one side of the upper surface and a second inclined surface M-ISb extending from the other side of the upper surface.

The second stopper pattern 203b of the second stopper structure MS may include an upper surface and both opposing inclined surfaces M-ISc and M-ISd extending downwardly from both opposing sides of the upper surface, respectively. The inclined surfaces M-ISc and M-ISd of the second stopper pattern 203b may include a first inclined surface M-ISc extending from one side of the upper surface and a second inclined surface M-ISd extending from the other side of the upper surface.

The light-emitting stack 134 may be disposed on the first electrode 133. In one example, the light-emitting stack 134 may include an organic material that emits each of light beams of different colors in different sub-pixels. However, embodiments of the present disclosure are not limited thereto. For example, the light-emitting stack 134 may emit light of one color among red, green, blue, and white. In another example, the light-emitting stack 134 may be made of an organic material that emits white light, and light of one color among red, green, and blue may be emitted through a corresponding color filter.

The light-emitting stack 134 may include a stack structure of a hole transporting layer (HTL), an emission material layer (EML), an electron transporting layer (ETL), a hole blocking layer (HBL), a hole injecting layer (HIL), an electron blocking layer (EBL), and an electron injecting layer (EIL). The stack structure may include a multi-stack structure in which at least two stacks are stacked. The emission material layer (EML) of the light-emitting stack 134 may emit light via recombination of holes injected from the first electrode 133 and electrons injected from the second electrode 135 therein.

The light-emitting stack 134 may be formed on an entire surface of the display area AA so as to cover the first electrode 133 and an exposed portion of the upper surface of the bank 132.

The second electrode 135 may be disposed on the light-emitting stack 134. The second electrode 135 may be formed to cover the light-emitting stack 134. The second electrode 135 may be commonly formed across the plurality of pixels. The second electrode 135 may include a transparent metal oxide such as indium tin oxide (ITO) or indium zinc oxide (IZO). Alternatively, the second electrode 135 may include a single-layer or multi-layer structure including a reflective metal film made of silver (Ag), aluminum (Al), gold (Au), nickel (Ni), chromium (Cr), and/or compounds thereof.

The encapsulation stack 140 may be disposed on the light-emitting element ED. The encapsulation stack 140 protects the light-emitting element ED from external oxygen or moisture. The encapsulation stack 140 may cover the display area AA and extend to the non-display area NAA surrounding the display area AA.

The encapsulation stack 140 may include a multilayer structure in which a first encapsulation layer 141, a second encapsulation layer 143, and a third encapsulation layer 145 are stacked. The encapsulation stack 140 may have a configuration in which the second encapsulation layer 143 is disposed between the first encapsulation layer 141 and the third encapsulation layer 145.

The first encapsulation layer 141 may be disposed on the second electrode 135. The first encapsulation layer 141 may include an inorganic insulating material. For example, the first encapsulation layer 141 may include at least one inorganic insulating material selected from among silicon nitride (SiNx), silicon oxide (SiOx), and silicon oxynitride (SiON).

The second encapsulation layer 143 may cover the first encapsulation layer 141 and have a thickness sufficient to obtain a flat upper surface. The second encapsulation layer 143 may prevent foreign substances from penetrating into the light-emitting element ED. The second encapsulation layer 143 may include an organic insulating material. For example, the second encapsulation layer 143 may include at least one material selected from among epoxy, polyimide, polyethylene, and acrylate.

Referring to FIG. 6, overflow of the organic insulating material of the second encapsulation layer 143 may be blocked or reduced by the first stopper structure TS in the non-display area NAA.

The third encapsulation layer 145 may be disposed on the second encapsulation layer 143. The third encapsulation layer 145 may include an inorganic insulating material. For example, the third encapsulation layer 145 may include at least one inorganic insulating material selected from among silicon nitride (SiNx), silicon oxide (SiOx), and silicon oxynitride (SiON).

As shown in FIG. 6, the third encapsulation layer 145 may extend to cover the second encapsulation layer 143 and the second stopper structure MS and an exposed portion of an upper surface of the dam DM.

Referring to FIG. 3 and FIG. 6, the touch stack 150 may be disposed on the third encapsulation layer 145 of the encapsulation stack 140. The touch stack 150 may include a touch buffer layer 151, a touch insulation layer 153, and a plurality of touch electrodes 155. The plurality of touch electrodes 155 may include a plurality of touch conductive patterns 154 and a plurality of bridge electrodes 152. The plurality of touch conductive patterns 154 and the plurality of bridge electrodes 152 may be disposed in different layers. For example, the plurality of bridge electrodes 152 may be disposed on the touch buffer layer 151, while the plurality of touch conductive patterns 154 may be disposed on a touch insulation layer 153.

The touch insulating layer 153 may be disposed between the touch conductive pattern 154 and the bridge electrodes 152. The plurality of touch conductive patterns 154 may be disposed on the touch insulating layer 153 and may be arranged so as to be spaced apart from each other. The bridge electrode 152 may electrically connect adjacent touch conductive patterns 154 to each other. To this end, the touch conductive pattern 154 may extend through the touch insulating layer 153 so as to be electrically connected to the bridge electrode 154.

Each of the touch conductive pattern 154 and the bridge electrode 152 may include a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto.

As shown in FIG. 6, the touch buffer layer 151 and the touch insulation layer 153 may be disposed on top of the first stopper structure TS and the second stopper structure MS and may extend so as to be disposed on top of the dam DM.

The sealing layer 160 may be disposed on the touch stack 150. The sealing layer 160 may have a sufficient thickness so as to cover a step caused by the touch stack 150 and obtain a flat upper surface. The sealing layer 160 may prevent foreign substances, moisture, or oxygen from penetrating into the touch stack 150.

The sealing layer 160 may include an organic insulating material. Referring to FIG. 6, the sealing layer 160 may be disposed on top of the first stopper structure TS and the second stopper structure MS, and may extend so as to be disposed on top of the dam DM.

The encapsulation stack 140 may be disposed to prevent or at least reduce moisture, oxygen, or foreign substances from penetrating into the light-emitting element ED or the transistor TR disposed in the display area AA. The encapsulation stack 140 may include the first encapsulation layer 141 and the third encapsulation layer 145 including the inorganic insulating material, and the second encapsulation layer 143 including the organic insulating material. The second encapsulation layer 143 may be disposed between the first encapsulation layer 141 and the third encapsulation layer 145 and may prevent defects caused by foreign substances. The second encapsulation layer 143 may be formed to have a sufficient thickness and may be made of an organic insulating material having fluidity. Accordingly, in order to prevent or at least reduce the organic insulating material having fluidity of the second encapsulation layer 143 from overflowing, the structures such as the first stopper structure TS, the second stopper structure MS, and the dam DM may be arranged to be spaced apart from each other.

Each of the structures such as the first stopper structure TS, the second stopper structure MS, and the dam DM may include the upper surface and both opposing inclined surfaces extending downwardly from both opposing sides of the upper surface, respectively.

When the inclination angle of each of the inclined surfaces of each of the structures approaches 90 degrees, a seam may occur in the process of forming the insulating films including the inorganic insulating material covering the structures. The insulating films including the inorganic insulating material may include the third encapsulation layer 145, the touch buffer layer 151, and the touch insulating layer 153.

For example, as the area size of the bezel area including the non-display area NAA is reduced, the space between adjacent ones of the structures such as the first stopper structure TS, the second stopper structure MS, and the dam DM is narrowed. When the inclination angle of each of the inclined surfaces of each of the structures disposed in the narrow space approaches 90 degrees, the insulating films including the inorganic insulating material do not entirely fill the space between adjacent ones of the structures such that the seam may occur. The seam that occurs in the space between adjacent ones of the structures may act as a path along which the moisture invades, thereby causing a defect in the display area. Accordingly, the inclination angle of each of the inclined surfaces of each of the structures may be smaller than 90 degrees and may be sized such that the structures may prevent the second encapsulation layer 143 from overflowing.

The inclination angle of each of the inclined surfaces of each of the structures including the first stopper structure TS, the second stopper structure MS and the dam DM may be affected by a size of an area where the first electrode 133 is disposed on the inclined surface of each of the structures.

For example, referring to FIG. 5 and FIG. 6, the first electrode 133 may be formed on the first layer 201a of the dam DM, and an exposure process may be performed to form the second layer 201b of the dam DM on the first electrode 133. An organic insulating material may be applied on the first electrode 133, and then a patterning process including an exposure process may be performed thereon to form the second layer 201b of the dam DM.

As shown in FIG. 5, when the first electrode 133 covers all of the inclined surfaces M-ISa, M-ISb, M-ISc, M-ISd, and D-ISb of the second stopper structure MS and the dam DM, overexposure may occur. For example, the first electrode 133 may include a single-layer or multi-layer structure including a reflective metal film made of silver (Ag), aluminum (Al), gold (Au), nickel (Ni), chromium (Cr), and/or compounds thereof.

When the first electrode 133 covers all of the inclined surfaces M-ISa, M-ISb, M-ISc, M-ISd, and D-ISb of the second stopper structure MS and the dam DM, an amount of light reflected from the reflective metal film included in the first electrode 133 may increase. Accordingly, an exposure amount larger than an exposure amount required to form the second layer 201b of the dam DM may be irradiated. As a result, the inclination angle of the inclined surface D-ISb of the second layer 201b of the dam DM may be brought into being smaller than an angle range in which the dam DM may prevent the second encapsulation layer 143 from overflowing.

Alternatively, the inclination angle of the inclined surface D-ISb of the second layer 201b of the dam DM may be brought into being closer to 90 degrees. As a result, the insulating films 145, 151, and 153 including the inorganic insulating material disposed on top of the dam DM may not entirely fill the space between the structures DM and MS, such that the defect such as the seam may occur. Thus, in the seam, the space between the structures DM and MS may not entirely filled, and thus the seam may act as a moisture permeation path. As a result, the moisture may invade into the display area AA through the moisture penetration path, thereby causing a problem in which the pixel does not emit light.

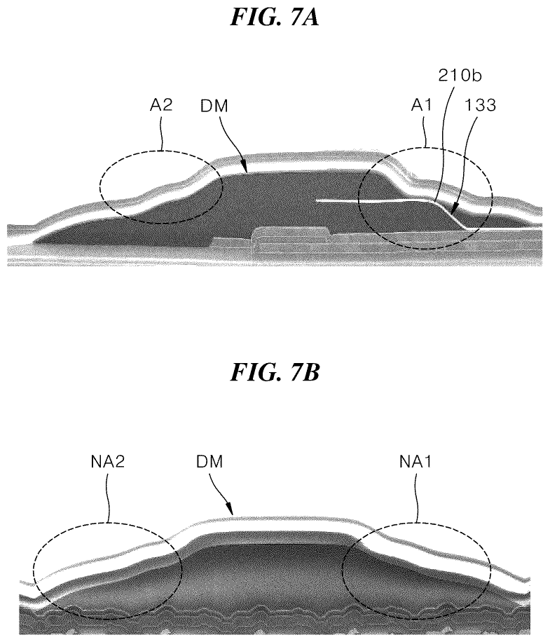

FIGS. 7A and 7B are diagrams showing the inclined surface shape of the dam.

Referring to FIGS. 7A and 7B, the dam DM may include the upper surface and both opposing inclined surfaces respectively extending downwardly from both opposing sides of the upper surface. The first electrode 133 may be disposed on one side inclined surface A1 of the dam DM (FIG. 7A). Then, the exposure process is performed to form the second layer 201b of the dam DM on the first electrode 133, such that the second layer 201b of the dam DM formed on one side inclined surface A1 on which the first electrode 133 is disposed is formed to have a thickness smaller than a thickness of the second layer 201b of the dam DM disposed on the other side inclined surface A2 on which the first electrode 133 is not disposed. Thus, it may be identified that an exposure amount larger than an exposure amount required to form the second layer 201b of the dam DM may be irradiated due to the first electrode 133.

Furthermore, as shown in FIG. 7B, when the first electrode 133 is not disposed on both opposing inclined surfaces NA1 and NA2 of the dam DM, it may be identified that respective portions of the second layers of the dam DM on both opposing inclined surfaces NA1 and NA2 of the dam DM are formed to be symmetrical with each other.

Accordingly, in some embodiments of the present disclosure, a configuration may be proposed in which a size of the area of the first electrode 133 disposed on each of the dam DM and the second stopper structure MS may be reduced such that an exposure amount larger than an exposure amount required to form the second layer 201b of the dam DM which results from the first electrode 133 may be prevented from being irradiated.

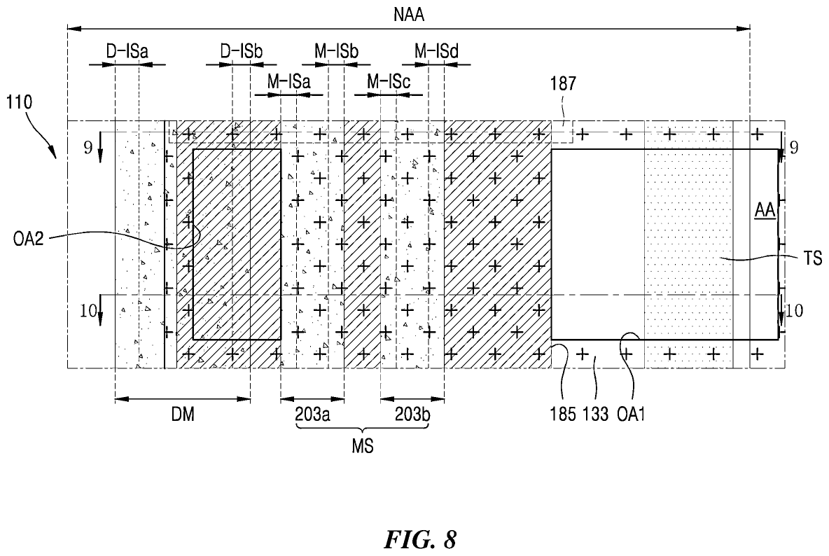

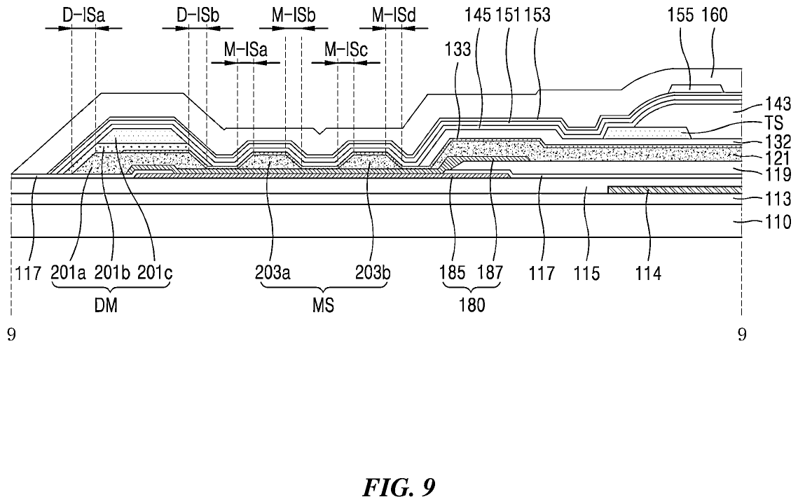

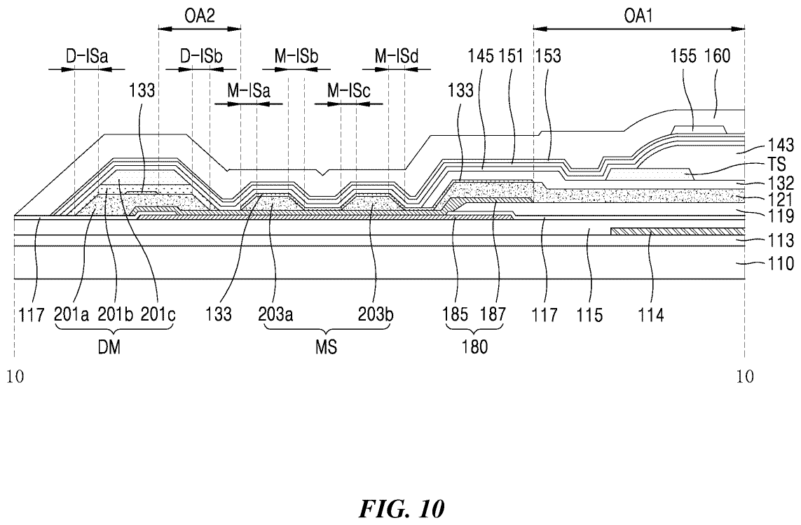

FIGS. 8 to 10 are diagrams showing another embodiment of the present disclosure. FIG. 8 is enlarged plan views showing an area 8 of FIG. 1 according to one embodiment. FIG. 9 is a cross-sectional view taken along a line 9-9 of FIG. 8 according to one embodiment. FIG. 10 is a cross-sectional view taken along a line 10-10 of FIG. 8 according to one embodiment. FIGS. 8 to 10 are substantially the same as FIGS. 5 and 6 except for a location of the opening. Thus, the same reference numerals are assigned to the same components as those in FIGS. 5 and 6, and redundant descriptions thereof may be omitted or simplified.

Referring to FIGS. 8 to 10, the first electrode 133 according to another embodiment of the present disclosure may have a plurality of openings OA1 and OA2 defined therein.

The plurality of openings OA1 and OA2 may include the first opening OA1 and the second opening OA2. In an area where the second opening OA2 is not disposed, the first electrode 133 may be disposed on the dam DM, the second stopper structure MS, and the first stopper structure TS, as shown in FIG. 9.

The first opening OA1 may overlap a portion of the non-display area NAA adjacent to the display area AA. For example, the first opening OA1 may be positioned to overlap the first stopper structure TS. The second opening OA2 may be positioned so as to overlap the space between the second stopper structure MS and the dam DM. The second opening OA2 may overlap at least a portion of one side inclined surface of the dam DM vertically.

Referring to FIG. 10, the second opening OA2 may expose the second inclined surface D-ISb of the dam DM and the space between the first stopper pattern 203a and the dam DM. The inclined surface of the dam DM may be exposed through the second opening OA2. For example, a portion of the second inclined surface D-ISb of the first layer 201a of the dam DM may not be covered with the first electrode 133 so as to be exposed. At least a portion of the first electrode 133 may be disposed on the upper surface of the first layer 201a.

Thus, in the exposure process for forming the second layer 201b, an exposure amount larger than an exposure amount required to form the second layer 201b of the dam DM which results from the first electrode 133 may not be irradiated onto the second inclined surface D-ISb of the first layer 201a of the dam DM.

Accordingly, the inclination angle of the inclined surface D-ISb of the second layer 201b of the dam DM may be maintained in an angular range in which the dam DM may prevent or at least reduce the second encapsulation layer 143 from overflowing. Furthermore, the inclination angle of the inclined surface of the dam DM may be maintained, such that the occurrence of the seam may be prevented when the insulating films 145, 151, and 153 are deposited.

The second layer 201b of the dam DM may be in surface contact with the second inclined surface D-ISb of the first layer 201a. A side inclined surface of the first layer 201a facing one side surface of the second stopper structure MS may contact the second layer 201b.

Due to the second opening OA2, a spacing may be defined between the first stopper pattern 203a of the second stopper structure MS and the dam DM. The first electrode 133 may not be disposed in the spacing. Accordingly, an insulating layer may be disposed in the spacing between the second stopper structure MS and the dam DM. For example, the insulating layer may include at least one of the insulating films 145, 151, and 153.

In another embodiment of the present disclosure, the area in which the first electrode 133 is disposed may be reduced using the second opening OA2, thereby reducing the amount of the light reflected from the first electrode 133. Accordingly, an exposure amount larger than an exposure amount required to form the second layer 201b of the dam DM which results from the first electrode 133 may not be irradiated onto the second inclined surface D-ISb of the first layer 201a of the dam DM. As a result, the defect such as the seam acting as the moisture penetration path which may occur when the angle of the inclined surface of the dam DM is smaller than a target angle range due to the exposure amount larger than the exposure amount required to form the second layer 201b of the dam DM may be suppressed. Accordingly, the defect due to the moisture penetration may be prevented from occurring in the display apparatus.

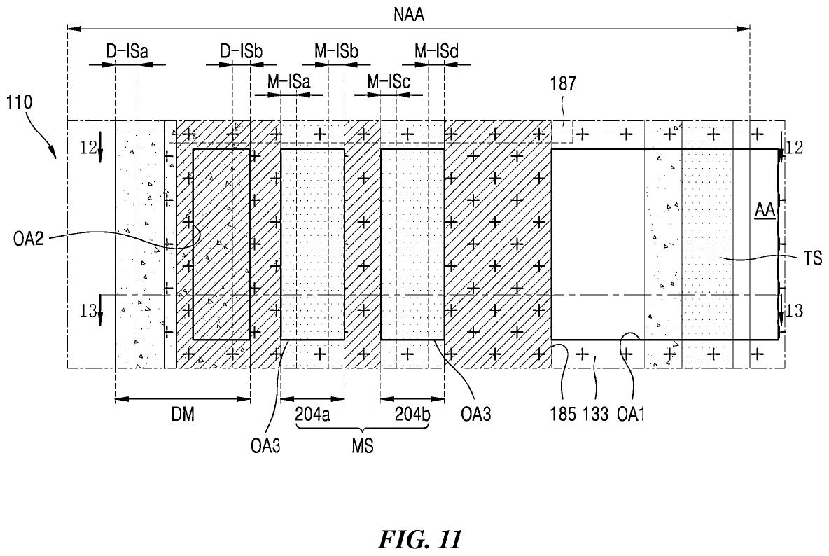

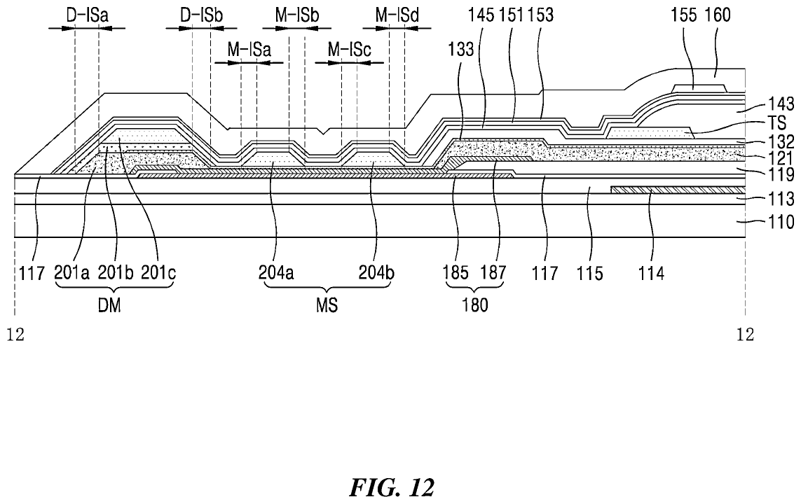

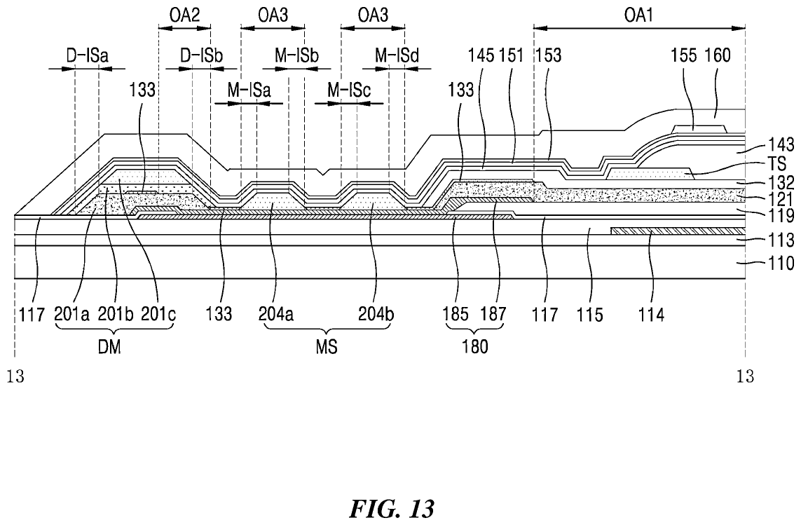

FIGS. 11 to 13 are diagrams showing still another embodiment of the present disclosure. FIG. 11 is enlarged plan views showing an area 11 of FIG. 1 according to one embodiment. FIG. 12 is a cross-sectional view taken along a line 12-12 of FIG. 11 according to one embodiment. FIG. 13 is a cross-sectional view taken along a line 13-13 of FIG. 11 according to one embodiment. FIGS. 11 to 13 are substantially the same as FIGS. 5 and 6 except for some configurations. Thus, the same reference numerals are assigned to the same components as those in FIGS. 5 and 6, and redundant descriptions thereof may be omitted or simplified.

Referring to FIGS. 11 to 13, according to still another embodiment of the present disclosure, the dam DM may include a structure in which the first layer 201a, the second layer 201b, and the third layer 201c are sequentially stacked vertically and upwardly. In an embodiment, the first layer 201a of the dam DM may include the same material as a material of the second planarization layer 121, the second layer 201b may include the same material as a material of the bank 132, and the third layer 201c may include the same material as a material of the spacer SP. However, embodiments of the present disclosure are not limited thereto.

The second stopper structure MS disposed between the dam DM and the first stopper structure TS may include a plurality of patterns. For example, the second stopper structure MS may include a third stopper pattern 204a and a fourth stopper pattern 204b. A space may be defined between the third stopper pattern 204a and the fourth stopper pattern 204b. Although still another embodiment of the present disclosure illustrates two stopper patterns 204a and 204b, embodiments of the present disclosure are not limited thereto. Referring to FIG. 13, the first electrode 133 may be disposed in the space between the first stopper pattern 203a and the second stopper pattern 203b of the second stopper structure MS. However, embodiments of the present disclosure are not limited thereto.

The third and fourth stopper patterns 204a and 204b of the second stopper structure MS may be formed together with the third layer 201c of the dam DM during the process of forming the spacer SP. The third and fourth stopper patterns 204a and 204b of the second stopper structure MS and the third layer 201c of the dam DM may include the same material. However, embodiments of the present disclosure are not limited thereto. Each of the third and fourth stopper patterns 204a and 204b may include the same shape as that of the third layer 201c of the dam DM. The third and fourth stopper patterns 204a and 204b may be disposed on the second power line 187. For example, a vertical level of an upper surface of each of the third and fourth stopper patterns 204a and 204b may be lower than a vertical level of an upper surface of the third layer 201c of the dam DM.

The first electrode 133 may have a plurality of openings OA1, OA2, and OA3 defined therein. The plurality of openings OA1, OA2 and OA3 may include the first opening OA1, the second opening OA2, and the third opening OA3. As shown in FIG. 12, in an area where the second opening OA2 and the third opening OA3 are not disposed, the first electrode 133 may extend from the dam DM toward the second stopper structure MS and the first stopper structure TS. Since the second stopper structure MS includes the same material as a material of the third layer 201c of the dam DM, the first electrode 133 may be in contact with a back surface of the second stopper structure MS.

The first opening OA1 may overlap a portion of the non-display area NAA adjacent to the display area AA. For example, the first opening OA1 may overlap the first stopper structure TS. The second opening OA2 may overlap a portion of an upper surface of the dam DM and the second inclined surface D-ISb of the dam DM. The third opening OA3 may overlap the second stopper structure MS.

Referring to FIG. 11 and FIG. 13, the second opening OA2 of the first electrode 133 may expose the second inclined surface D-ISb of the dam DM and the space between the second stopper structure MS and the dam DM. The inclined surface of the dam DM may be exposed through the second opening OA2. For example, a portion of the second inclined surface D-ISb of the first layer 201a of the dam DM may not be covered with the first electrode 133 so as to be exposed.

The third opening OA3 may expose the inclined surface of each of the third stopper pattern 204a and the fourth stopper pattern 204b of the second stopper structure MS. For example, as shown in FIG. 13, the first inclined surface M-ISa and the second inclined surface M-ISb of the third stopper pattern 204a, and the first inclined surface M-ISc and the second inclined surface M-ISd of the fourth stopper pattern 204b may be exposed through the third opening OA3.

Accordingly, an exposure amount larger than an exposure amount required to form the second layer 201b of the dam DM which results from the first electrode 133 may not be irradiated onto the second inclined surface D-ISb of the first layer 201a of the dam DM. Thus, the inclination angle of the inclined surface of the dam DM may be maintained, thereby preventing the seam from occurring when depositing the insulating films 145, 151, and 153. Accordingly, the defect due to the moisture penetration may be prevented from occurring in the display apparatus.

Furthermore, a space between the third stopper pattern 204a and the fourth stopper pattern 204b which are relatively narrow may be secured. Accordingly, the insulating films 145, 151, and 153 including the inorganic insulating material may fill the space between the third stopper pattern 204a and the fourth stopper pattern 204b such that the seam may be suppressed. Accordingly, the defect due to the moisture penetration may be prevented from occurring in the display apparatus.

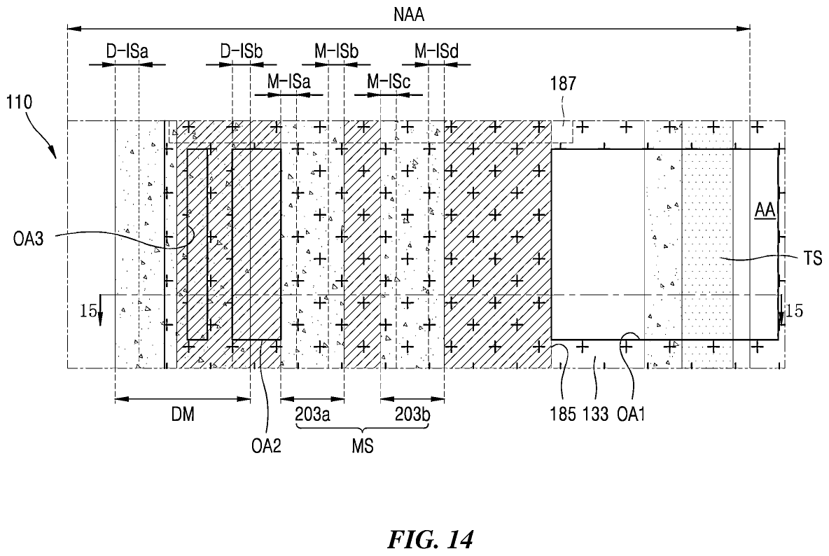

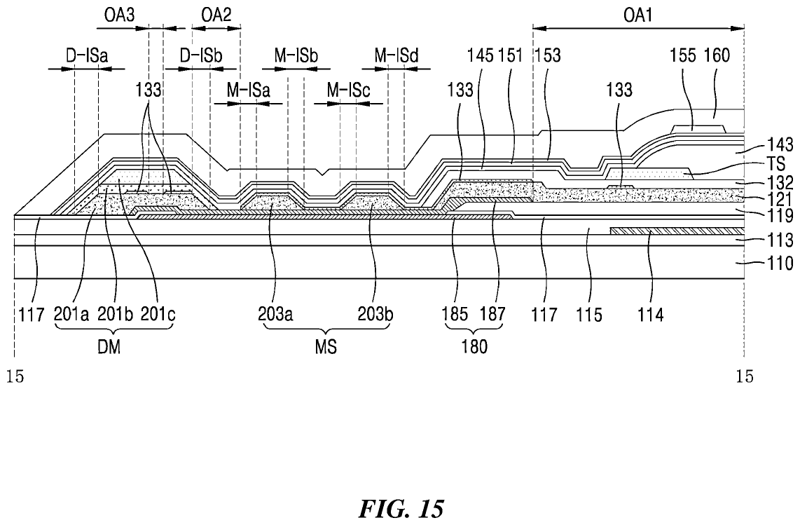

FIG. 14 and FIG. 15 are diagrams showing still yet another embodiment of the present disclosure. FIG. 14 is enlarged plan views showing an area 14 of FIG. 1 according to one embodiment. FIG. 15 is a cross-sectional view taken along a line 15-15 of FIG. 14 according to one embodiment. FIGS. 14 and 15 are substantially identical to FIGS. 5 and 6 except for positions of the openings. Thus, the same reference numerals are assigned to the same components as those in FIGS. 5 and 6, and redundant descriptions thereof may be omitted or simplified.

Referring to FIG. 14 and FIG. 15, according to still yet another embodiment of the present disclosure, the dam DM may include a structure in which the first layer 201a, the second layer 201b, and the third layer 201c are sequentially stacked vertically and upwardly. The second stopper structure MS positioned between the dam DM and the first stopper structure TS may include a plurality of patterns. For example, the second stopper structure MS may include the first stopper pattern 203a and the second stopper pattern 203b. A space may be defined between the first stopper pattern 203a and the second stopper pattern 203b. Although still yet another embodiment of the present disclosure illustrates two stopper patterns 203a and 203b, embodiments of the present disclosure are not limited thereto. The first and second stopper patterns 203a and 203b of the second stopper structure MS may be formed together with the first layer 201a of the dam DM. The first and second stopper patterns 203a and 203b may be disposed on the second power line 187. Accordingly, a vertical level of an upper surface of each of the first and second stopper patterns 203a and 203b may be lower than a vertical level of the upper surface of the third layer 201c of the dam DM.

The first electrode 133 may have a plurality of openings OA1, OA2, and OA3 defined therein. The plurality of openings OA1, OA2, and OA3 may include the first opening OA1, the second opening OA2, and the third opening OA3. As shown in FIG. 15, in an area where the second opening OA2 and the third opening OA3 are not disposed, the first electrode 133 may extend from the dam DM toward the second stopper structure MS and the first stopper structure TS and may extend to the display area AA.

The first opening OA1 may overlap a portion of the non-display area NAA adjacent to the display area AA. For example, the first opening OA1 may overlap the first stopper structure TS. The second opening OA2 may overlap a space between the second stopper structure MS and the dam DM.

The second opening OA2 may expose the second inclined surface D-ISb of the dam DM and the space between the second stopper structure MS and the dam DM. The inclined surface of the dam DM may be exposed through the second opening OA2. For example, a portion of the second inclined surface D-ISb of the first layer 201a of the dam DM may not be covered with the first electrode 133 so as to be exposed.

The third opening OA3 overlap the upper surface of the first layer 201a of the dam DM. Since the first electrode 133 is disposed between the second opening OA2 and the third opening OA3, the area in which the first electrode 133 is disposed in an entire area of the display apparatus may be relatively increased, thereby reducing electrical resistance.

Furthermore, an exposure amount larger than an exposure amount required to form the second layer 201b of the dam DM which results from the first electrode 133 may not be irradiated onto the second inclined surface D-ISb of the first layer 201a of the dam DM due to the second opening OA2 defined in the first electrode 133. Thus, the inclination angle of the inclined surface of the dam DM may be maintained. Accordingly, when depositing one or more insulating layers, for example, the insulating films 145, 151, and 153 in the space between the second inclined surface D-ISb of the dam DM and the first stopper pattern 203a of the second stopper structure MS, the seam may be prevented from occurring in the space. Accordingly, the defect due to the moisture penetration may be prevented from occurring in the display apparatus.

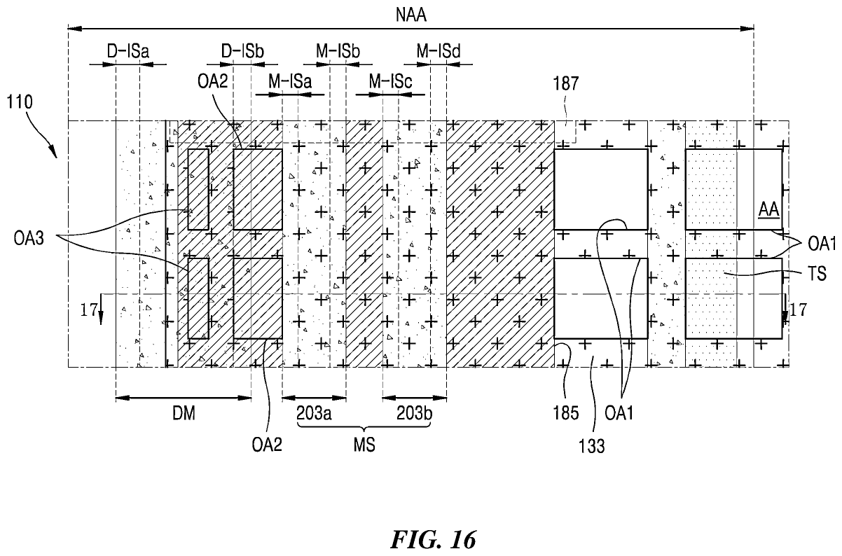

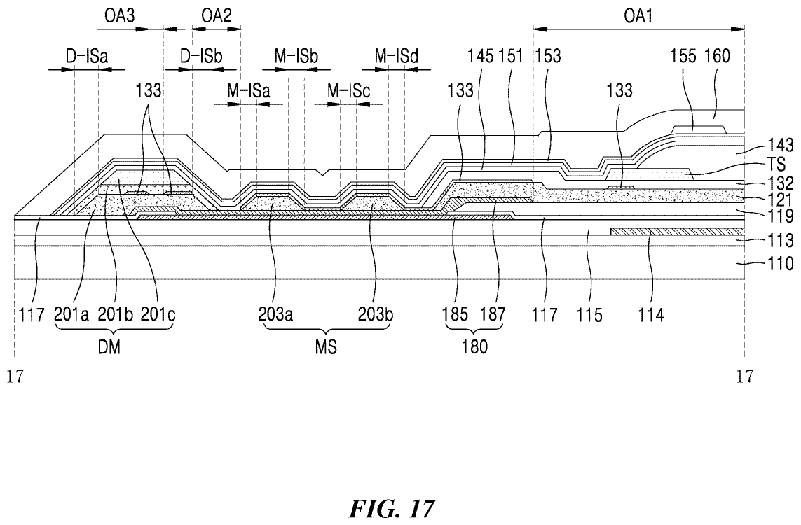

FIG. 16 and FIG. 17 are diagrams showing still yet another embodiment of the present disclosure. FIG. 16 is enlarged plan views showing an area 16 of FIG. 1 according to one embodiment. FIG. 17 is a cross-sectional view taken along a line 17-17 of FIG. 16 according to one embodiment. FIG. 16 and FIG. 17 are substantially the same as FIG. 15 and FIG. 16 except for a shape of the opening. Thus, the same reference numerals are assigned to the same components as those in FIGS. 15 and 16, and redundant descriptions thereof may be omitted or simplified.

Referring to FIG. 16 and FIG. 17, according to still yet another embodiment of the present disclosure, the first opening OA1, the second opening OA2, and the third opening OA3 differ from those in FIG. 14 to FIG. 16 in that each of the first opening OA1, the second opening OA2, and the third opening OA3 includes a plurality of sub-openings arranged in a grid manner and spaced from each other.

For example, referring to FIG. 17, the first opening OA1 may overlap a portion of the non- display area NAA closest to the display area AA. The first opening OA1 may overlap the first stopper structure TS. The first opening OA1 may include a plurality of sub-openings spaced from each other. For example, the first opening OA1 may include an arrangement of four sub-openings spaced apart from each other. The first electrode 133 may be disposed between adjacent sub-openings. However, the shape of the first opening OA1 is not limited to the shape as shown.

The second opening OA2 may expose the second inclined surface D-ISb of the dam DM and the space between the second stopper structure MS and the dam DM. The inclined surface of the dam DM may be exposed through the second opening OA2. For example, a portion of the second inclined surface D-ISb of the first layer 201a of the dam DM may not be covered with the first electrode 133 so as to be exposed. The second opening OA2 may include an arrangement of a plurality of sub-openings spaced from each other. For example, the second opening OA2 may include two sub-openings spaced apart from each other in the length direction of the dam DM. The first electrode 133 may be disposed between adjacent sub-openings.

The third opening OA3 overlap the upper surface of the first layer 201a of the dam DAM. The third opening OA3 may include an arrangement of a plurality of sub-openings spaced from each other. For example, the third opening OA3 may include two sub-openings spaced apart from each other in the length direction of the dam DM. The first electrode 133 may be disposed between adjacent sub-openings.

According to still yet another embodiment of the present disclosure, each of the first opening OA1, the second opening OA2, and the third opening OA3 may include the plurality of sub-openings arranged so as to be spaced apart from each other. Furthermore, the first electrode 133 may be disposed between adjacent ones of the plurality of sub-openings. Thus, the area in which the first electrode 133 is disposed in an entire area of the display apparatus may be relatively increased, thereby reducing electrical resistance.

Furthermore, an exposure amount larger than an exposure amount required to form the second layer 201b of the dam DM which results from the first electrode 133 may not be irradiated onto the second inclined surface D-ISb of the first layer 201a of the dam DM due to the second opening OA2 defined in the first electrode 133. Thus, the inclination angle of the inclined surface of the dam DM may be maintained. Accordingly, when depositing one or more insulating layers, for example, the insulating films 145, 151, and 153 in the space between the second inclined surface D-ISb of the dam DM and the first stopper pattern 203a of the second stopper structure MS, the seam may be prevented from occurring in the space. Accordingly, the defect due to the moisture penetration may be prevented from occurring in the display apparatus.

The display apparatus according to various embodiments of the present disclosure may be described as follows.

One aspect of the present disclosure provides a display apparatus includes a substrate including a display area, and a non-display area surrounding at least a portion of the display area, wherein a light-emitting element is disposed in the display area; a dam disposed in the non-display area; a stopper structure disposed in the non-display area, wherein the stopper structure is positioned between the dam and the display area; and a first electrode of the light-emitting element, wherein the first electrode includes a plurality of openings, wherein the plurality of openings are disposed in the non-display area of the substrate.

In accordance with some embodiments of the display apparatus, at least one of the plurality of openings at least partially overlaps one side inclined surface of the dam vertically.

In accordance with some embodiments of the display apparatus, the stopper structure includes a first stopper structure and a second stopper structure spaced apart from each other, wherein the first stopper structure is disposed adjacent to the display area, wherein the second stopper structure is disposed between the dam and the first stopper structure.

In accordance with some embodiments of the display apparatus, the second stopper structure includes a plurality of patterns arranged so as to be spaced apart from each other, wherein the first electrode is disposed in a space between adjacent ones of the plurality of patterns, wherein at least one of the plurality of openings defined in the first electrode at least partially overlaps an inclined surface of the second stopper structure vertically.

In accordance with some embodiments of the display apparatus, the dam includes: a first layer including an upper surface and both opposing inclined surfaces respectively extending downwardly from both opposing side of the upper surface; a second layer disposed over the first layer; and a third layer disposed over the second layer, wherein the first electrode is disposed over the first layer, wherein at least one of the plurality of openings at least partially overlaps one side inclined surface of the dam vertically.

In accordance with some embodiments of the display apparatus, the second stopper structure is spaced apart from the dam, wherein the second stopper structure and the first layer of the dam are disposed in the same layer, wherein at least a portion of the first electrode is disposed on the upper surface of the first layer, wherein a side inclined surface of the first layer facing one side surface of the second stopper structure contacts the second layer.

In accordance with some embodiments of the display apparatus, at least one insulating layer is disposed in a space between the second stopper structure and the dam.

In accordance with some embodiments of the display apparatus, the second stopper structure is spaced apart from the dam and includes the same material as a material of the first layer of the dam.

In accordance with some embodiments of the display apparatus, the second stopper structure is spaced apart from the dam and includes the same material as a material of the third layer of the dam.

In accordance with some embodiments of the display apparatus, the first stopper structure includes the same material as a material of the third layer of the dam.

In accordance with some embodiments of the display apparatus, the second stopper structure has a closed curve shape surrounding at least a portion of an outer perimeter of the first stopper structure in the plan view.

In accordance with some embodiments of the display apparatus, the first electrode includes a reflective metal film.

In accordance with some embodiments of the display apparatus, the plurality of openings defined in the first electrode include: a first opening overlapping the first stopper structure vertically; and a second opening at least partially overlapping an inclined surface of the dam vertically.

In accordance with some embodiments of the display apparatus, the plurality of openings defined in the first electrode further include a third opening overlapping an upper surface of the first layer of the dam vertically.

In accordance with some embodiments of the display apparatus, each of the plurality of openings includes a plurality of sub-openings arranged in a grid manner and spaced apart from each other.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display apparatus comprising:
a substrate including a display area and a non-display area surrounding at least a portion of the display area, wherein a light-emitting element is in the display area;
a dam in the non-display area;
a stopper structure in the non-display area, the stopper structure between the dam and the display area; and
a first electrode of the light-emitting element, the first electrode extending from the display area to the non-display area,
wherein the first electrode includes a plurality of openings in the non-display area of the substrate.

2. The display apparatus of claim 1, wherein at least one of the plurality of openings at least partially overlaps one side inclined surface of the dam vertically.

3. The display apparatus of claim 1, wherein the stopper structure includes a first stopper structure and a second stopper structure spaced apart from each other,
wherein the first stopper structure is adjacent to the display area and the second stopper structure is between the dam and the first stopper structure.

4. The display apparatus of claim 3, wherein the second stopper structure includes a plurality of patterns that are spaced apart from each other,
wherein the first electrode is in a space between adjacent ones of the plurality of patterns,
wherein at least one of the plurality of openings in the first electrode at least partially overlaps an inclined surface of the second stopper structure vertically.

5. The display apparatus of claim 3, wherein the dam includes:
a first layer including an upper surface and both opposing inclined surfaces respectively extending downwardly from both opposing side of the upper surface;
a second layer over the first layer; and
a third layer over the second layer,
wherein the first electrode is over the first layer,
wherein at least one of the plurality of openings at least partially overlaps one side inclined surface of the dam vertically.

6. The display apparatus of claim 5, wherein the second stopper structure is spaced apart from the dam, wherein the second stopper structure and the first layer of the dam are in a same layer,
wherein at least a portion of the first electrode is on the upper surface of the first layer,
wherein a side inclined surface of the first layer facing one side surface of the second stopper structure contacts the second layer.

7. The display apparatus of claim 6, wherein at least one insulating layer is in a space between the second stopper structure and the dam.

8. The display apparatus of claim 5, wherein the second stopper structure is spaced apart from the dam and includes a same material as a material of the first layer of the dam.

9. The display apparatus of claim 5, wherein the second stopper structure is spaced apart from the dam and includes a same material as a material of the third layer of the dam.

10. The display apparatus of claim 5, wherein the first stopper structure includes a same material as a material of the third layer of the dam.

11. The display apparatus of claim 3, wherein the second stopper structure has a closed curve shape surrounding at least a portion of an outer perimeter of the first stopper structure in a plan view.

12. The display apparatus of claim 1, wherein the first electrode includes a reflective metal film.

13. The display apparatus of claim 5, wherein the plurality of openings in the first electrode include:
a first opening overlapping the first stopper structure vertically; and
a second opening at least partially overlapping an inclined surface of the dam vertically.

14. The display apparatus of claim 13, wherein the plurality of openings in the first electrode further include a third opening overlapping an upper surface of the first layer of the dam vertically.

15. The display apparatus of claim 1, wherein each of the plurality of openings includes a plurality of sub-openings arranged in a grid manner and spaced apart from each other.

16. The display apparatus of claim 3, wherein the plurality of openings in the first electrode overlap a partial area of the first stopper structure.

17. The display apparatus of claim 5, wherein first layer has a width that is smaller than a width of the second layer, and the third layer covers an upper surface of the second layer.

18. The display apparatus of claim 5, wherein the second stopper structure has a shape that is a same as a shape of the first layer of the dam.

19. The display apparatus of claim 5, wherein the second stopper structure includes a plurality of patterns that are spaced apart from each other and each of the plurality of patterns of the second stopper structure includes a shape that is a same as a shape of the third layer of the dam.

20. The display apparatus of claim 19, wherein a vertical level of an upper surface of each of the plurality of patterns of the second stopper structure is lower than a vertical level of an upper surface of the third layer of the dam.

21. The display apparatus of claim 13, wherein the second opening overlaps a space between the second stopper structure and the dam.

22. The display apparatus of claim 15, wherein the first electrode is between adjacent ones of the plurality of sub-openings.

23. The display apparatus of claim 14, wherein the first electrode is between the second opening and the third opening.

24. The display apparatus of claim 5, wherein the second layer of the dam on one side inclined surface on which the first electrode is disposed has a thickness that is smaller than a thickness of the second layer of the dam on another side inclined surface on which the first electrode is not disposed.
